(19) United States
(12) Patent Application Publication
(10) Pub. No.: US 2025/0349562 A1
(43) Pub. Date: Nov. 13, 2025

(54) APPARATUS AND METHODS FOR CHEMICAL MECHANICAL POLISHING

(71) Applicant: TAIWAN SEMICONDUCTOR MANUFACTURING COMPANY, LTD., Hsinchu (TW)

(72) Inventors: Jeng-Chi LIN, Hsinchu City (TW); Chi-Hsiang SHEN, Tainan City (TW); Da-Shiuan CHIOU, Taipei City (TW); Te-Chien HOU, Kaohsiung City (TW); Wei-Ting LEE, Taipei City (TW); Yu-Jen SHEN, Hsinchu City (TW); Tang-Kuei CHANG, Tainan City (TW); Hui-Chi HUANG, Hsinchu County (TW); Kei-Wei CHEN, Tainan City (TW)

(21) Appl. No.: 18/657,842

(22) Filed: May 8, 2024

(51) Int. Cl. H01L 21/67; H01L 21/321; H01L 21/677

(52) U.S. Cl. CPC H01L 21/67028; H01L 21/3212; H01L 21/67196; H01L 21/67742; H01L 21/67772

(57) ABSTRACT

Embodiments of the present disclosure relate a CMP tool and methods for planarization a substrate. The CMP tool is symmetrical arrangement to balance transfer time and improve throughput. The CMP tool comprises a plurality of polishing stations arranged around a transfer chamber. A substrate transfer robot may be disposed in the transfer chamber. The plurality of polishing stations are arranged at substantially equal distances from the substrate transfer robot, thereby, enabling substantially equal transfer times among the polishing stations. In some embodiments, the polishing stations and/or cleaning stations are disposed in closed chambers. During operation, inert gases, such as nitrogen, may be filled in closed chambers to prevent metal corrosion on substrate surfaces.

### BACKGROUND

During the manufacture of integrated circuits (ICs), multi-step sequences of semiconductor manufacturing processes are performed to gradually form electronic circuits on semiconductor substrates. One such semiconductor manufacturing process is chemical mechanical polishing (CMP). CMP is a process for smoothing or planarizing surfaces using a combination of chemical and mechanical forces. Among other things, CMP advantageously allows features of the electronic circuits to be more precisely formed.

As the device dimension scales down, byproducts, agglomerated abrasives, pad debris, slurry residues, and other particles on the substrate surface during conventional CMP process may cause higher level of defects, reducing product yield rate. Conventional CMP sequence may include long and non-uniform transfer times. Long transfer time may include metal corrosion or particle defects on CMP surfaces. Embodiments of the present disclosure provide apparatus and methods with reduced and uniform transfer times in a CMP sequencer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic block diagram of a CMP tool in accordance with some embodiments of the present disclosure.

FIG. 1B schematically illustrates an exemplary CMP sequence performed with the CMP tool in FIG. 1A.

FIGS. 1C and 1D schematically demonstrate alternative CMP sequences using the CMP tool of FIG. 1A.

FIGS. 1E and 1F schematically demonstrate polishing station maintenance without shutting down in the CMP tool of FIG. 1A.

FIGS. 1G and 1H schematically demonstrate cleaning station maintenance without shutting down in the CMP tool of FIG. 1A.

FIG. 2A is a schematic block diagram of a CMP tool in accordance with some embodiments of the present disclosure.

FIG. 2B schematically illustrates an exemplary CMP sequence performed with the CMP tool in FIG. 2A.

FIG. 3 is a schematic perspective view of a transfer chamber with stacked stations according to embodiments of the present disclosure.

FIG. 4 is a flow chart of a method for processing substrates according to embodiments of the present disclosure.

FIGS. 5A-5C schematically illustrate a semiconductor device during fabrication at various stage of processing.

FIG. 6 is a schematic block diagram of a CMP tool in accordance with some embodiments of the present disclosure.

FIG. 7A is a schematic block diagram of a CMP tool in accordance with some embodiments of the present disclosure. FIG. 7B is a schematic view of a dual blade robot. FIG. 7C is a schematic view of a robot blade.

FIGS. 8A-8B schematically demonstrate various processing sequences using CMP tools according to embodiments of the present disclosure.

FIGS. 9A-9C schematically demonstrate a cleaner/polisher with removable door according to embodiments of the present disclosure.

FIGS. 10A-10B schematically demonstrate a cleaner/polisher with inert gas fill function according to embodiments of the present disclosure.

FIG. 11 schematically demonstrate modular CMP tools according to embodiments of the present disclosure.

FIGS. 12A-12D schematically demonstrate trouble shooting or maintenance mode of polishing/cleaning modules according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure relate a CMP tool and methods for planarization a substrate. Particularly, embodiments of the present disclosure provide a CMP tool with symmetrical arrangement to balance transfer time and improve throughput. In some embodiments, the polishing tool comprises a plurality of polishing stations arranged around a transfer chamber. A substrate transfer robot may be disposed in the transfer chamber. In some embodiments, the plurality of polishing stations are arranged at substantially equal distances from the substrate transfer robot, thereby, enabling substantially equal transfer times among the polishing stations. In some embodiments, the polishing tool further comprises a second transfer chamber and a plurality of cleaning stations arranged around the second transfer chamber. In some embodiments, the polishing stations and/or cleaning stations are disposed in closed chambers. During operation, inert gases, such as nitrogen, may be filled in closed chambers to prevent metal corrosion on substrate surfaces.

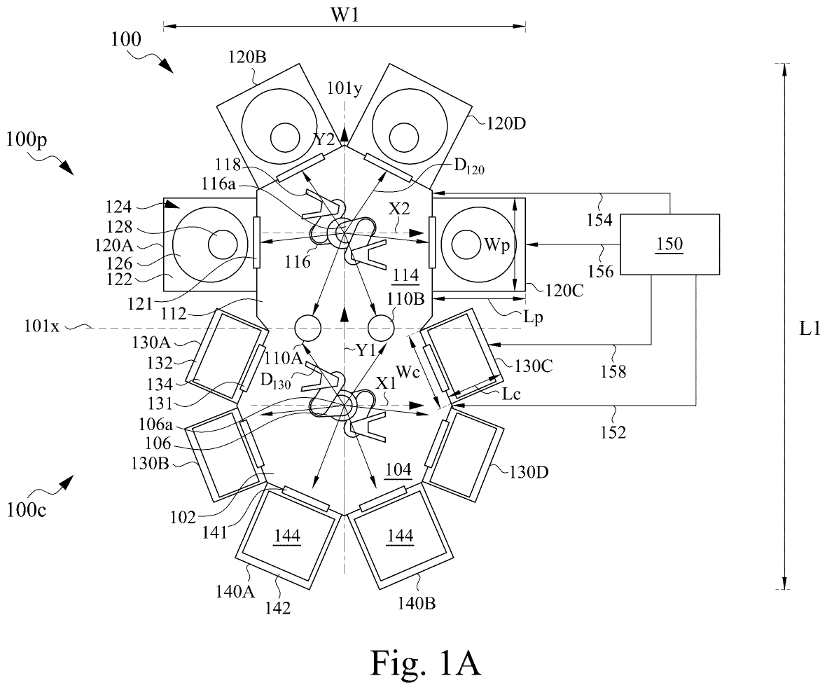

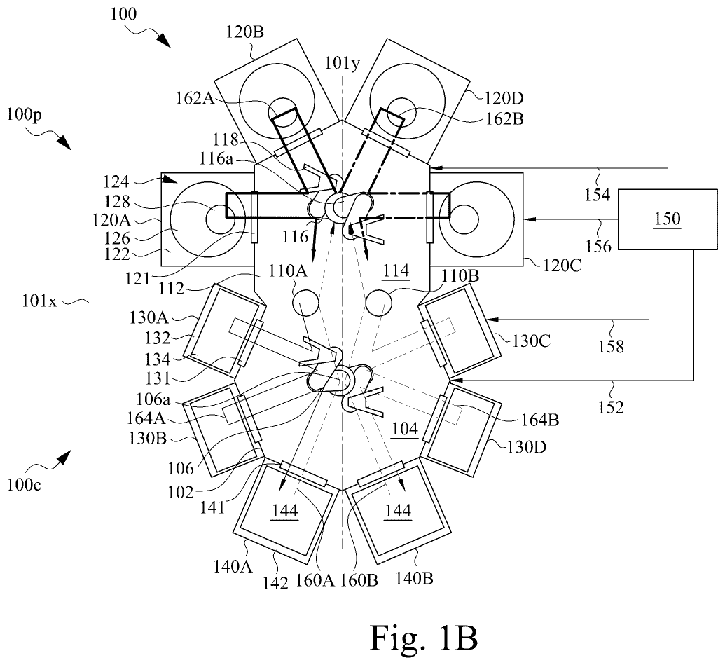

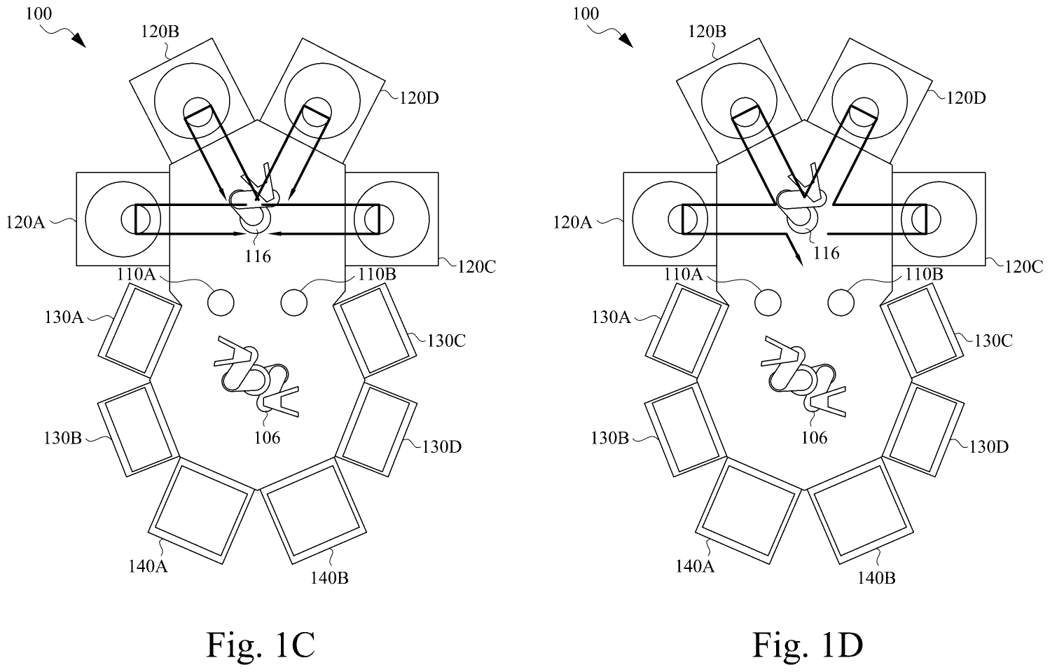

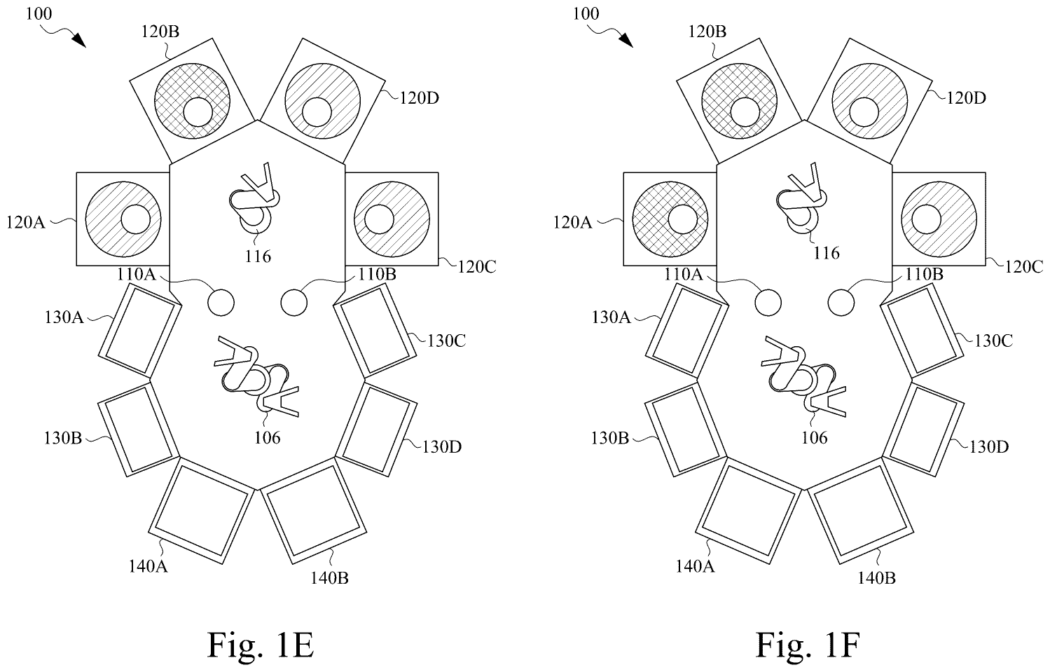

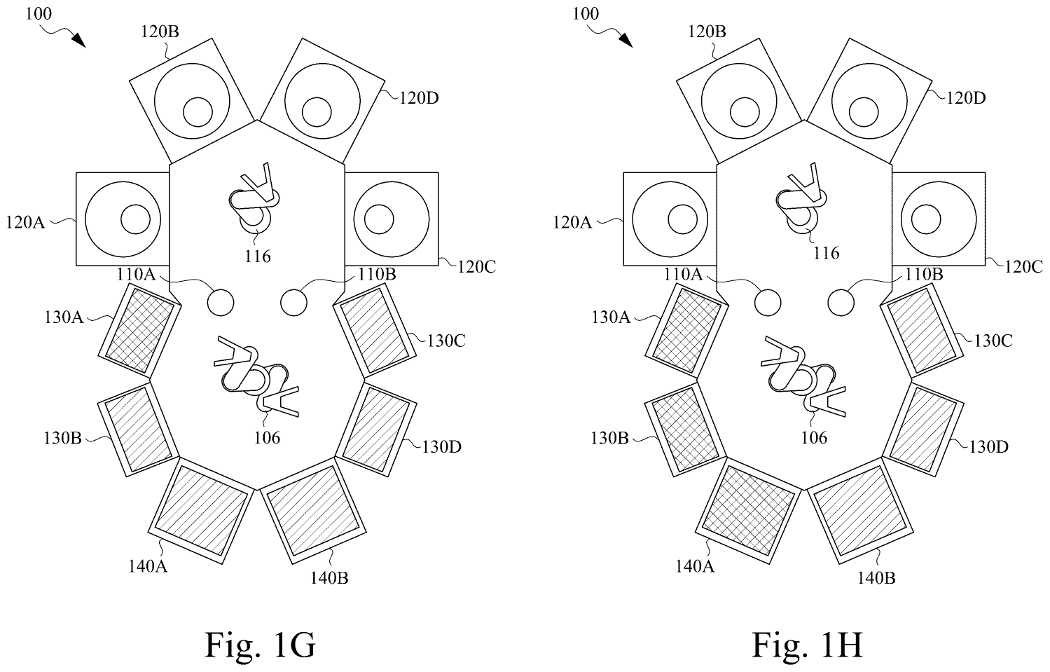

FIG. 1A is a schematic block diagram of a CMP tool 100 in accordance with some embodiments of the present disclosure. The CMP tool 100 may further includes a controller to facilitate control of the planarizing, cleaning, and transfer processes.

The CMP tool 100 includes a first transfer chamber 102 and a second transfer chamber 112 connected by one or more wafer stations 110 (wafer stations 110A, 110B are shown in FIG. 1A, collectively wafer stations 110). One or more interface chambers 140 (interface chambers 140A, 140B are shown in FIG. 1A, collectively interface chambers 140) may be attached to the first transfer chamber 102.

A plurality of polishing chambers 120 (polishing chambers 120A, 120B, 120C, 120D are shown in FIG. 1A, collectively polishing chambers 120) are connected to the second transfer chamber 112. Even though four polishing chambers 120 are shown in the CMP tool 100, less or more polishing chambers 120 may be attached to the second transfer chamber 112 according to process needs. The second transfer chamber 112 may be referred to as a polisher transfer chamber.

A plurality of cleaning chambers 130 (cleaning chambers 130A, 130B, 130C, 130D are shown in FIG. 1A, collectively cleaning chambers 130) are connected to the first transfer chamber 102. Even though four cleaning chambers 130 are shown in the CMP tool 100, less or more cleaning chambers 130 may be attached to the first transfer chamber 102 according to process needs. The first transfer chamber 102 may be referred to as a cleaner transfer chamber.

The first transfer chamber 102 includes a chamber body defining a transfer volume 104. A substrate transfer robot 106 is disposed in the transfer volume 104. The substrate transfer robot 106 may include one or more robot blades. Each robot blade is configured to transfer a substrate among the cleaning chambers 130, the interface chambers 140 and the wafer stations 110. In some embodiments, the substrate transfer robot 106 includes two substrate transfer blades. During the operation, the two substrate transfer blades may be dedicated to clean substrates and non-clean substrates to avoid cross contamination.

In some embodiments, the polishing chambers 130, the interface chambers 140 and the wafer stations 110 are symmetrically arranged around the first transfer chamber 102. As shown in FIG. 1A, the first transfer chamber 102 may be symmetrical about an axis Y1, and the cleaning chambers 130, the interface chambers 140 and the wafer stations 110 are disposed in mirror image about the axis Y1.

In some embodiments, a central axis 106a of the substrate transfer robot 106 may be disposed at an intersection of the X1 axis and the Y1 axis. The substrate transfer robot 106 may be rotatable about the central axis 106a. The cleaning chambers 130 may be disposed at substantially equal distances D₁₃₀ from the central axis 106a of the substrate transfer robot 106 so that the transfer time between any two cleaning chambers 130 is substantially the same. Similarly, the interface chambers 140A and 140B are disposed at substantially the same distance to the central axis 106a of the substrate transfer robot 106. The wafer stations 110A and 110B are disposed at substantially the same distance to the central axis 106a of the substrate transfer robot 106.

In some embodiments, the distances between the central axis 106a of the substrate transfer robot 106 and the interface chambers 140/the wafer stations 110 may be different from the distances D₁₃₀ between the central axis 106a of the substrate transfer robot 106 and the cleaning chambers 130. In other embodiments, the interface chambers 140/the wafer stations 110 may be disposed at substantially equal distances D₁₃₀ from the central axis 106a of the substrate transfer robot 106.

The second transfer chamber 112 includes a chamber body defining a transfer volume 114. In some embodiments, the transfer volume 114 of the second transfer chamber 112 is isolated from the transfer volume 104 of the first transfer chamber 102. The wafer stations 110A and 110B may be selectively connected to the transfer volumes 114 and 104. Alternatively, the transfer volume 114 of the second transfer chamber 112 and the transfer volume 104 of the first transfer chamber 102 are in fluid communication and the wafer stations 110A and 110B are open to the transfer volumes 114 and 104.

A substrate transfer robot 116 is disposed in the transfer volume 114. The substrate transfer robot 116 may include one or more robot blades. Each robot blade is configured to transfer a substrate among the polishing chambers 120 and the wafer stations 110. In some embodiments, the substrate transfer robot 116 includes two substrate transfer blades. During the operation, the two substrate transfer blades may be dedicated to polished substrates and non-polished substrates to avoid cross contamination.

In some embodiments, the polishing chambers 130 and the wafer stations 110 are symmetrically arranged around the second transfer chamber 112. As shown in FIG. 1A, the second transfer chamber 112 may be symmetrical about an axis Y2, and the polishing chambers 130 and the wafer stations 110 are disposed in mirror image about the axis Y2. In some embodiments, the axis Y1 of the first transfer chamber 102 and the axis Y2 of the second transfer chamber 112 are disposed along one line. In other embodiments, the axis Y1 of the first transfer chamber 102 and the axis Y2 of the second transfer chamber 112 are arranged along the same direction but staggered. In other embodiments, the axis Y1 of the first transfer chamber 102 and the axis Y2 of the second transfer chamber 112 are arranged at an angle relative to each other.

In some embodiments, a central axis 116a of the substrate transfer robot 116 may be disposed at an intersection of the X2 axis and the Y2 axis. The substrate transfer robot 116 may be rotatable about the central axis 116a. The polishing chambers 120 may be disposed at substantially equal distances D₁₂₀ from the central axis 116a of the substrate transfer robot 116 so that the transfer time between any two polishing chambers 120 is substantially the same. Similarly, the wafer stations 110A and 110B are disposed at substantially the same distance to the central axis 116a of the substrate transfer robot 116.

In some embodiments, the distances between the central axis 116a of the substrate transfer robot 116 and the wafer stations 110 may be different from the distances D₁₂₀ between the central axis 116a of the substrate transfer robot 116 and the polishing chambers 120. In other embodiments, the wafer stations 110 may be disposed at substantially equal distances D₁₂₀ from the central axis 116a of the substrate transfer robot 116.

Each polishing chamber 120 may include a chamber body defining a chamber volume 122. In some embodiments, each polishing chamber 120 has a width Wp and a length Lp. The polishing chamber 120 may be attached to the second transfer chamber 112 along the width Wp and extending outwardly from the second transfer chamber 112 for the length Lp. In some embodiments, the width Wp is in a range between about 700 mm and about 1200 mm. In some embodiments, the length Lp is in a range between about 700 mm and about 1200 mm.

In some embodiments, the chamber volume 122 may be selectively closed. The polishing chamber 120 may include a door 121 to selectively connect the chamber volume 122 with the chamber volume 114 of the second transfer chamber 112. In some embodiments, the door 121 is a sliding door. The door 121 may be closed during polishing to prevent byproducts of polishing and contaminants from entering the chamber volume 114 of the second transfer chamber 112 and/or maintain an inert processing environment in the chamber volume 122.

A polishing station 124 may be disposed in the chamber volume 122 of each polishing chamber 120. Each polishing station 124 is configured to perform a particular polishing operation. Each polishing station 124 may include a platen 126, and a carrier head 128. Each polishing station 124 may further include a pad conditioner (not shown) and a slurry nozzle (not shown).

The platen 126 includes a rotatable table covered by a polishing pad (not shown) having a polishing surface. In some embodiments, the polishing pad may be adhered to the platen 126 through vacuum force. The platen 126 can be provided with a series of distributed holes operatively connected to a vacuum system allowing the polishing pad to be subjected to an appropriate vacuum. The level of vacuum can be monitored and/or controlled using conventional pressure monitors and fixtures to uniformly distribute the vacuum along the underside of the polishing pad and adhere the pad to the platen 126 thereby resulting in a controlled flatness of the respective polishing surface. Exemplary polishing pads can be comprised of cast or sliced polyurethane, polyurethane impregnated polyester felt, or another suitable material.

The carrier head 128 is configured to retain a substrate facing down towards the platen 126 to be polished. A substrate may be held by vacuum to the carrier head 128 or held thereto by a backing film. In some embodiments, the substrate is encompassed by a retainer ring attached to the carrier head 128. During polishing, the carrier head 128 may rotate the substrate about a central axis.

The carrier head 128 may be connected to a frame of the polishing station 124 by a pivot arm, which allows the carrier head 128 to move relative to the platen 126. During polishing, the carrier head 128 may also swing back and forth relative to the platen 126 to enable a uniform polishing rate across the substrate surface.

The slurry nozzle is configured to introduce a polishing slurry to the polishing pad on the platen 126. The polishing slurry may include abrasive particles and chemicals to enable chemical mechanical polishing process. Exemplary slurries may comprise abrasive particles suspended in an alkaline, neutral or acidic solution, depending upon the process requirement, i.e., chemical etchants and colloid particles. In some embodiments, the polishing slurry may include one or more chemicals such as oxidizing agents, chelating agents, corrosion inhibitors, stabilizing agents, and/or pH adjusting agents. Designs of the polishing pad and composition of the slurry are selected according to handle different polishing tasks, such as wafers with different material composition to be removed, amount of material to be removed, etc. The pad conditioner is configured to prepare and condition the surface of the polishing pad on the platen 126 during, before and/or after CMP processes. The pad conditioner 122 may include a conditioner head attached to a pivot arm.

During polishing, the platen 126 and the carrier head 128 are rotated about different axis to remove material and even out irregular topographies on the substrate. In some embodiments, the carrier head 128 may also swing related to the platen 126. The rotating carrier head 128 presses the substrate 102 against the rotating polishing pad on the platen 126, and slurry containing chemical etchants and colloid particles are introduced using the slurry nozzle 124 onto the polishing pad. Through this active rotation of a substrate on a polishing pad on the platen 126 under pressure in a presence of a polishing medium, irregularities on the wafer surface are removed during one or more CMP processes thereby resulting in a planarization of the substrate.

During operation, one robot blade of the substrate transfer robot 116 may extend into the chamber volume 122 of a polishing chamber 120 via the door 121 to load a substrate being processed on to the carrier head 128 for polishing. The door 121 may be closed during polishing. After polishing is complete in a polishing chamber 120, the door 121 may open and one robot blade of the substrate transfer robot 116 enters the chamber volume 122 via the door 121 to unload the substrate from the carrier head 128. The substrate transfer robot 116 may transfer the substrate to the next polishing chamber 120 or to the wafer station 110.

The wafer station 110 may include a load cup configured to exchange a substrate with the substrate transfer robots 106 and 116. For example, the substrate transfer robots 106 and 116 may drop a substrate on the load cup and pick up a substrate disposed on the load cup. In some embodiments, each wafer station 110 may include a chamber volume wherein one or more load cups is disposed. The chamber volume of the wafer station 110 may include two doors configured to selectively open to the first transfer chamber 102 and the second transfer chamber 112.

Each cleaning chamber 130 may include a chamber body defining a chamber volume 132. In some embodiments, each cleaning chamber 130 has a width Wc and a length Lc. The cleaning chamber 130 may be attached to the first transfer chamber 102 along the width Wc and extending outwardly from the first transfer chamber 102 for the length Lc. In some embodiments, the width Wc is in a range between about 700 mm and about 1200 mm. In some embodiments, the length Lc is in a range between about 700 mm and about 1200 mm.

In some embodiments, the chamber volume 132 may be selectively closed. The cleaning chamber 130 may include a door 131 to selectively connect the chamber volume 132 with the chamber volume 104 of the first transfer chamber 102. In some embodiments, the door 131 is a sliding door. The door 131 may be closed during cleaning to prevent byproducts of cleaning and contaminants from entering the chamber volume 104 of the first transfer chamber 102 and/or maintain an inert processing environment in the chamber volume 132.

Each cleaning chamber 130 may include a cleaning station 134 disposed in the chamber volume 132. The cleaning stations 134 in each cleaning chamber 130 may be different device and/or configured differently to clean the substrate using different cleaning techniques. For example, the cleaning station 134 may be one of a pre-cleaning station, a brush cleaner, a megasonic cleaner, or a drying station depending on the cleaning sequence to be performed. In some embodiments, the CMP tool 100 may be configured to perform a two-step cleaning sequence. The cleaning chambers 130A and 130C may include a cleaning station for the first step cleaning, such as a brush cleaner, a spray nozzle cleaner or a buffer pad cleaner. The cleaning chambers 130B and 130D may include a drying station, such as Marangoni dryer using IPA vapor or a spin-rinse-dry station. In other embodiments, the cleaning stations 134 in the cleaning chambers 130A, 130B, 130C, and 130D includes a pre-cleaning station, a brush cleaner, a megasonic cleaner, and a drying station respectively for a four-step cleaning sequence.

During operation, one robot blade of the substrate transfer robot 106 may extend into the chamber volume 132 of a cleaning chamber 130 via the door 131 to load a substrate being processed in the cleaning station 134 disposed therein. The door 131 may be closed during cleaning. After cleaning is complete in a cleaning chamber 130, the door 131 may open and one robot blade of the substrate transfer robot 106 enters the chamber volume 132 via the door 131 to retrieve the substrate from the cleaning station 134. The substrate transfer robot 106 may transfer the substrate to the next cleaning chamber 130 or to the interface chamber 140.

In some embodiments, the interface chamber 140 may include a chamber body defining a chamber volume 142. In some embodiments, the chamber volume 142 may be selectively closed. The interface chamber 140 may include a door 141 to selectively connect the chamber volume 142 with the chamber volume 104 of the first transfer chamber 102. The door 141 may be selectively closed to prevent cross contamination.

In some embodiments, the interface chamber 140 is configured to receive one or more front opening unified pods (FOUPs) 144 may be received in the chamber volume 142. The substrate transfer robot 106 may retrieve and drop off substrates to the FOUPs 144 via the door 141. In some embodiments, the substrate transfer robot 106 may include two robot blades. One robot blade may be designated to handling substrates prior to being processed in the CMP tool 100 and during cleaning sequence, and the other robot blade may be designated to handling substrates after completing the cleaning sequence in the CMP tool 100, to reduce cross contamination.

In alternative embodiments, the interface chambers may be omitted, and the one or more FOUPs 144 may be directedly interfacing with the doors 141 of the first transfer chamber 102.

The CMP tool 100 may be divided into a polishing module 100p above a dividing axis 101x and a cleaning module 100c below the diving axis 101x. As shown in FIG. 1A, the CMP tool 100 is a symmetrical device with polishing chambers 120 and cleaning chambers 130 arranged about transfer chambers 102, 112. The polishing chambers 120 and the cleaning chambers 130 are symmetrically arranged. As shown in FIG. 1A, the CMP tool 100 is symmetrically arranged about a central axis 101y. In some embodiments, the polishing stations 120 in the polishing module 100p are arranged symmetrically about the central axis 101y. The cleaning stations 130 in the cleaning module 100c are arranged symmetrically about the central axis 101y. In some embodiments, the CMP tool 100 may have a footprint with a width W1 and a length L1. In some embodiments, the width W1 is in a range between about 1800 mm and about 3300 mm. In some embodiments, the length L1 is in a range between about 4000 mm and about 6000 mm.

In some embodiments, the CMP tool 100 is connected to a gas supply 150. The gas supply 150 is configured to provide one or more inert gas towards various chambers in the CMP tool 100. For example, the gas supply 150 may be configured to supply an inert gas, such as nitrogen, helium, argon, or a combination thereof. The CMP tool 100 may include a conduit 152 configured to supply an inert gas from the gas supply 150 to the chamber volume 104 of the first transfer chamber 102. In some embodiments, the chamber volume 104 may be connected to an exhaust pump to enable a gas flow and maintaining a pressure in the first transfer chamber 102. In some embodiments, the chamber volume 104 may be maintained environment of inert gas at about one atmosphere pressure during operation. The CMP tool 100 may include a conduit 154 configured to supply an inert gas from the gas supply 150 to the chamber volume 114 of the second transfer chamber 112. In some embodiments, the chamber volume 1124 may be connected to an exhaust pump to enable a gas flow and maintaining a pressure in the second transfer chamber 112. In some embodiments, the chamber volume 114 may be maintained environment of inert gas at about one atmosphere pressure during operation.

The CMP tool 100 may include a plurality of conduits 156 configured to supply an inert gas from the gas supply 150 to the polishing chambers 120. In some embodiments, the chamber volume 122 of each polishing chamber 120 may be connected to an exhaust pump to enable a gas flow and maintaining a process pressure therein. In some embodiments, the chamber volume 122 may be maintained environment of inert gas at about one atmosphere pressure during operation.

The CMP tool 100 may include a plurality of conduits 158 configured to supply an inert gas from the gas supply 150 to the cleaning chambers 130. In some embodiments, the chamber volume 132 of each cleaning chamber 130 may be connected to an exhaust pump to enable a gas flow and maintaining a process pressure therein. In some embodiments, the chamber volume 132 may be maintained environment of inert gas at about one atmosphere pressure during operation.

As discussed above, the CMP tool 100 according to the present disclosure provides balanced transfer time with symmetrical tool design. The symmetrical design also enables parallel substrate paths, thereby, improving throughput. In some embodiments, the CMP tool 100 according to the present disclosure may be used to process substrates through two or more parallel paths, with substantially the same travel times, thus, improving throughput and wafer-to-wafer process uniformity. FIG. 1B schematically illustrates an exemplary CMP sequence with two parallel substrate paths through the CMP tool 100.

FIG. 1B illustrates a substrate path A and a substrate path B in the CMP tool 100. The substrate path A and the substrate path B include polishing chambers and cleaning chambers on the left and right side of the axis Y1 and axis Y2. The substrate path A includes a path 160A which passes through the interface chamber 140A to the wafer station 110A, a path 162A which passes through the polishing chambers 120B and 120A, and a path 164A which passes through the cleaning chambers 130A and 130B. The substrate path B includes a path 160B which passes through the interface chamber 140B to the wafer station 110B, a path 162B which passes through the polishing chambers 120D and 120C, and a path 164B which passes through the cleaning chambers 130C and 130D. The substrate path A and the substrate path B share the substrate transfer robots 106 and 116, and may be performed at a staggered manner. However, as shown in Table 1 below, corresponding transfers in the substrate path A and the substrate path B include substantially the same transfer distances, therefore, may be completed in substantially the same time durations.

TABLE 1

| Description of Process Sequence | Substrate Path A | Substrate Path B |
|---|---|---|
| Transfer 1 | 140A to 110A | 140B to 110B |
| From FOUP to wafer station | Travel Distance: 2*D₁₃₀ | Travel Distance: 2*D₁₃₀ |
| Transfer 2 | 110A to 120B | 110B to 120D |
| From Wafer station to first polishing | Travel Distance: 2*D₁₂₀ | Travel Distance: 2*D₁₂₀ |
| station | | |
| Rough Polish | 120B | 120D |
| Transfer 3 | 120B to 120A | 120D to 120C |
| From first polishing station to second | Travel Distance: 2*D₁₂₀ | Travel Distance: 2*D₁₂₀ |
| polishing station | | |
| Fine Polish | 120A | 120C |
| Transfer 4 | 120A to 110A | 120C to 110B |
| From second polishing station to wafer | Travel Distance: 2*D₁₂₀ | Travel Distance: 2*D₁₂₀ |
| station | | |
| Transfer 5 | 110A to 130A | 110B to 130C |
| From wafer station to the first cleaning | Travel Distance: 2*D₁₃₀ | Travel Distance: 2*D₁₃₀ |
| station | | |
| First cleaning | 130A | 130C |
| Transfer 6 | 130A to 130B | 130C to 130D |
| From first cleaning station to second | Travel Distance: 2*D₁₃₀ | Travel Distance: 2*D₁₃₀ |
| cleaning station | | |
| Second cleaning | 130B | 130D |
| Transfer 7 | 130B to 140A | 130D to 140B |
| From second cleaning station to FOUP | Travel Distance: 2*D₁₃₀ | Travel Distance: 2*D₁₃₀ |

In some embodiments, the substrate path A and the substrate path B may be used to perform the identical CMP sequences. The parallel substrate paths A and B improve throughput while maintaining wafer-to-wafer uniformity.

In other embodiments, the polishing chambers 120A, 120B on the left side and the polishing chambers 120C, 120D may be configured differently, and used to perform two different CMP processes independently via the substrate path A and the substrate path B. For example, some substrates may go through the substrate path A for oxide removal while other substrates may go through the substrate path B for metal removal.

The CMP tool 100 may be used to perform various CMP process sequences. FIG. 1C schematically demonstrates a process sequence according to one embodiment of the present disclosure. In FIG. 1C, the polishing operation may be completed using one polishing station. Substrates being polished may go through one of the four parallel substrate paths, each goes through one of the polishing chambers 120A, 120B, 120C, 120D. Because the polishing chambers 120A, 120B, 120C, and 120D are disposed at equal distances from the substrate transfer robot 116, transfer times to and fro the four polishing chambers 120A, 120B, 120C, 120D are substantially the same. Substrate to substrate uniformity is not affected by transfer times through different substrate paths. In FIG. 1C, the cleaning sequence is not shown. It should be noted that the cleaning sequence may be designed according to the process requirement. For example, each substrate path may include a separate cleaning chamber, or two substrate paths may share a cleaning sequence including two or more cleaning chambers, or all four substrate paths may share the same cleaning sequence.

FIG. 1D schematically demonstrates a process sequence according to one embodiment of the present disclosure. In FIG. 1D, the polishing operation may be completed using all four polishing chambers 120C, 120D, 120B, and 120A. Substrates being polished may go through four polishing chambers 120C, 120D, 120B, and 120A in any sequence. In FIG. 1D, the cleaning sequence is not shown. It should be noted that the cleaning sequence may be designed according to the process requirement. After being polished through the four polishing chambers 120, the substrates may sequentially go through the same cleaning chambers 130. In other embodiments, after being polished through the four polishing chambers 120, the substrates may split into two or more different cleaning sequences.

Individual polishing chambers and/or polishing chambers in CMP tools according to the present disclosure, such as the CMP tool 100, may be maintained independently without stopping the CMP tool 100. FIG. 1E schematically demonstrates an operation status of the CMP tool 100 in which the polishing chamber 120B is stopped for maintenance while other polishing chambers 120A, 120C, and 120D are running for process. FIG. 1F schematically demonstrates an operation status of the CMP tool 100 in which the polishing chambers 120A, 120B are stopped for maintenance while the polishing chambers 120C, and 120D are running for process. FIG. 1G schematically demonstrates an operation status of the CMP tool 100 in which the cleaning chamber 130A is stopped for maintenance while the other cleaning chambers 130B, 130C, 130D are running for process. FIG. 1H schematically demonstrates an operation status of the CMP tool 100 in which the cleaning chambers 130A, 130B and the interface chamber 140A are stopped for maintenance while the other cleaning chambers 130C, 130D, and the interface chamber 140B are running for process.

As discussed above, CMP tools according to the present disclosure may be configured to include various numbers of polish chambers and cleaning chambers.

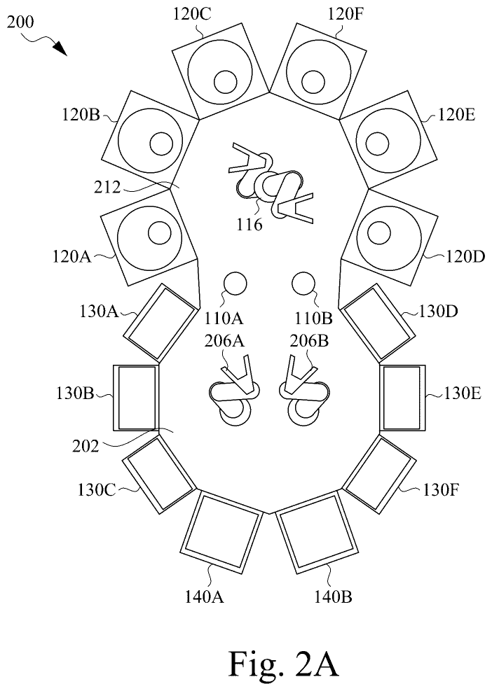

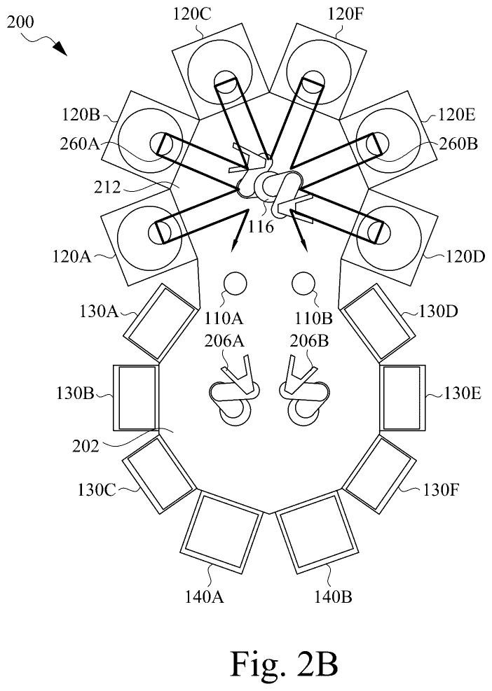

FIG. 2A is a schematic block diagram of a CMP tool 200 in accordance with some embodiments of the present disclosure. The CMP tool 200 is similar to the CMP tool 100 except that the CMP tool 200 includes a transfer chamber 202 having six cleaning chambers 130A, 130B, 130C, 130D, 130E, 130F (collectively 130) attached thereto, and a transfer chamber 212 having six polishing stations 120A, 120B, 120C, 120D, 120E, 120F attached thereto. In some embodiments, the transfer chamber 202 may include two substrate transfer robots 206A, 206B disposed therein. An additional substrate transfer robot may improve throughput.

FIG. 2B schematically illustrates an exemplary CMP sequence performed with the CMP tool 200 in FIG. 2A. In the operation sequence shown in FIG. 2A, the substrates being polished may follow a substrate path 260A and a substrate path 260B. The substrate path 260A passes through the polishing chambers 120C, 120B and 120A while the substrate path 260B passes the polishing chambers 120F, 120E, and 120D. Because the polishing chambers 120A, 120B, 120C, 120D, 120E, and 120F are disposed at equal distances from the substrate transfer robot 116, transfer times to and fro the six polishing chambers 120A, 120B, 120C, 120D, 120E, and 120F are substantially the same. Substrate to substrate uniformity is not affected by transfer times through the substrate paths 260A, 260B. In FIG. 2B, the cleaning sequence is not shown. It should be noted that the cleaning sequence may be designed according to the process requirement. For example, each substrate path may include a separate cleaning chamber, or two substrate paths may share a cleaning sequence including two or more cleaning chambers, or all four substrate paths may share the same cleaning sequence.

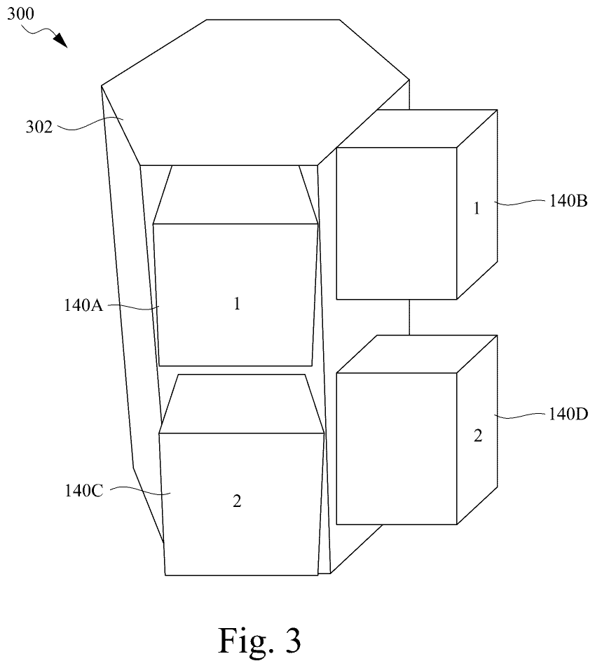

FIG. 3 is a schematic partial perspective view of a CMP tool 300 according to the embodiments of the present disclosure. The CMP tool 300 may be similar to the CMP tools 100, 200 above, except that the CMP tool 300 includes a transfer chamber 302 designed to connect with the polishing chambers 120, the cleaning chambers 130, and/or the interfacing chambers 140 in a stacked manner to improve throughput. In FIG. 3, interfacing chambers 140A and 140C are attached to the transfer chamber 302 in a stacked manner and interfacing chambers 140B and 140D are attached to the transfer chamber 302 in a stacked manner. Even though, not shown, the CMP tool 300 may include polishing chambers 120 and/or cleaning chambers 130 stacked over each other and attached to a transfer chamber.

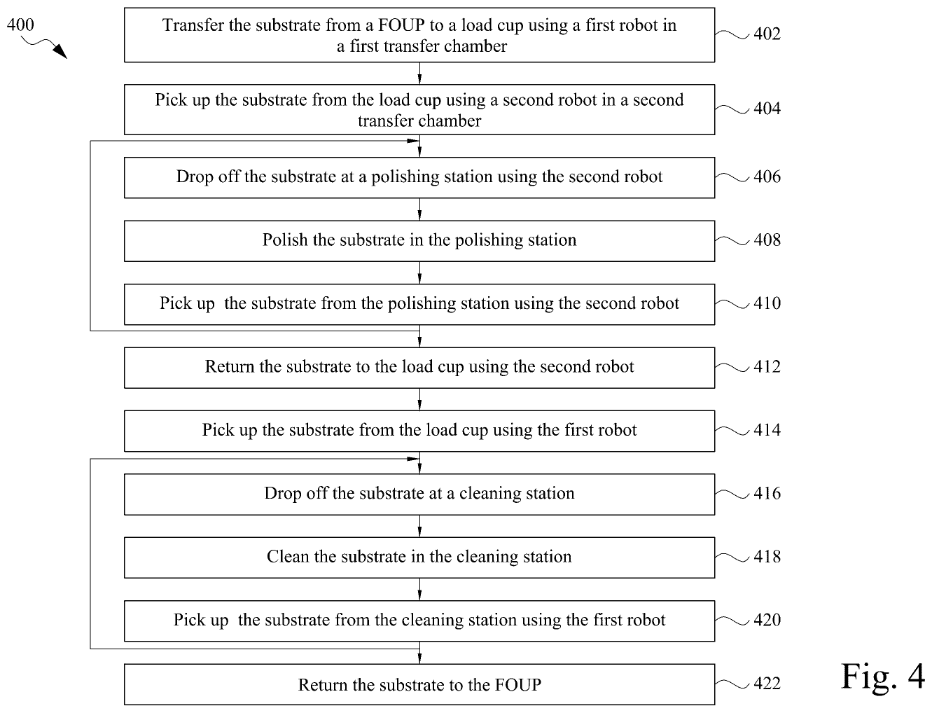

FIG. 4 is a flow chart of a method 400 for polishing substrates according to embodiments of the present disclosure. The method 400 may be performed using the CMP tools 100, 200, and 300 described above. For example, substrates being processed using the method 400 may follow the substrate path A or substrate path B in FIG. 1B. As discussed, the substrate paths A and B in FIG. 1B are parallel paths, and a substrate entering the CMP tool 100 may follow either path A or path B.

At operation 402, a substrate enters a CMP tool, such as the CMP tool 100, to be processed. For example, as shown in FIG. 1B, the substrate enters the CMP tool 100 from a FOUP 144 disposed in an interface chamber 140 through the first transfer chamber 102 to the wafer station 110. In some embodiments, the substrate may be transferred using a first robot blade of the substrate transfer robot 106 disposed in the first transfer chamber 102. In some embodiments, the first robot blade may be designated to handle substrates finishing the po robot bone of the FOUP 114.

At operation 404, the substrate is picked up from the wafer station by a substrate transfer robot disposed in a second transfer chamber. As shown in FIG. 1B, the substrate is picked up from the wafer station 110 by the substrate transfer robot 116 disposed in the second transfer chamber 112.

At operation 406, the substrate is dropped off by the substrate transfer robot to a first polishing chamber. As shown in FIG. 1B, the substrate is dropped off on the polishing chamber 120B or 120D by the substrate transfer robot 116. In some embodiments, the door 121 between the polishing chamber 120 and the transfer chamber 112 may first open allow the substrate transfer robot 116 and the substrate enter the polishing chamber 120. After the substrate is dropped off or transferred to the carrier head 128 in the polishing station 124, the substrate transfer robot 116 exits the polishing chamber 120 and the door 121 closes isolating the chamber volume 122 of the polishing chamber 120. In some embodiments, an inert gas is supplied to the chamber volume 122 to prevent corrosion on a surface of the substrate.

At operation 408, the substrate is polished in a first polishing station for a first polish, such as a rough polish. For example, as shown in FIG. 1B, the substrate is polished in the polishing chamber 120B or 120D. During polishing, the substrate is retained by the carrier head 128 facing down to the platen 126. The carrier head 128 rotates the substrate and pushes the substrate against the polishing pad on the rotating platen 126 to polish the substrate. In some embodiments, an inert gas is supplied to the chamber volume 122 during polishing. In some embodiments, the polishing chamber 120 may be maintain a pressure at about one atmosphere.

At operation 410, after the first polishing is complete, the substrate is picked up from the polishing chamber by the substrate transfer robot disposed in the second transfer chamber. As shown in FIG. 1B, the substrate is picked up from the carrier head 128 of the polishing station by the substrate transfer robot 116 disposed in the second transfer chamber 112. In some embodiments, the door 121 of the polishing chamber 120 may open to allow the substrate transfer robot 116 to enter.

Operations 406, 408, and 410 may be repeated one or more time for additional polishing process, such as a fine polishing in the polishing station 120A and 120C.

In operation 412, the substrate is returned to the wafer station. As shown in FIG. 1B, after all the polishing steps are performed, the substrate is returned to the wafer station 110.

At operation 414, the substrate is picked up from the wafer station by the substrate transfer robot disposed in the first transfer chamber. As shown in FIG. 1B, the substrate is picked up from the wafer station 110 by the substrate transfer robot 106 disposed in the first transfer chamber 102.

At operation 416, the substrate is dropped off by the substrate transfer robot to a first cleaning chamber. As shown in FIG. 1B, the substrate is dropped off on the cleaning chamber 130A or 130C by the substrate transfer robot 106. In some embodiments, the door 131 between the cleaning chamber 130 and the transfer chamber 102 may first open allow the substrate transfer robot 106 and the substrate to enter the cleaning chamber 130. After the substrate is dropped off in the cleaning chamber 130, the substrate transfer robot 106 exits the cleaning chamber 130 and the door 131 closes isolating the chamber volume 132 of the cleaning chamber 130. In some embodiments, an inert gas is supplied to the chamber volume 132 to prevent corrosion on a surface of the substrate during cleaning.

At operation 418, the substrate is cleaned in a first cleaning station for a first cleaning, such as a brush cleaning. For example, as shown in FIG. 1B, the substrate is cleaned in the cleaning chamber 130A or 130C. In some embodiments, an inert gas is supplied to the chamber volume 132 during cleaning. In some embodiments, the cleaning chamber 120 may be maintain a pressure at about one atmosphere.

At operation 420, after the first cleaning is complete, the substrate is picked up from the cleaning chamber by the substrate transfer robot disposed in the first transfer chamber. As shown in FIG. 1B, the substrate is picked up from the cleaning chamber 130A or 130C by the substrate transfer robot 106 disposed in the first transfer chamber 102. In some embodiments, the door 131 of the cleaning chamber 130 may open to allow the substrate transfer robot 106 to enter.

Operations 416, 418, and 420 may be repeated one or more time for additional cleaning process, such as a second cleaning process performed in the cleaning chambers station 130B and 130D.

In operation 422, the substrate is returned to the FOUP and exit the CMP tool. As shown in FIG. 1B, after all the cleaning steps are performed, the substrate is returned to the FOUP 144 in the interface chamber 140 and exit the CMP tool 100.

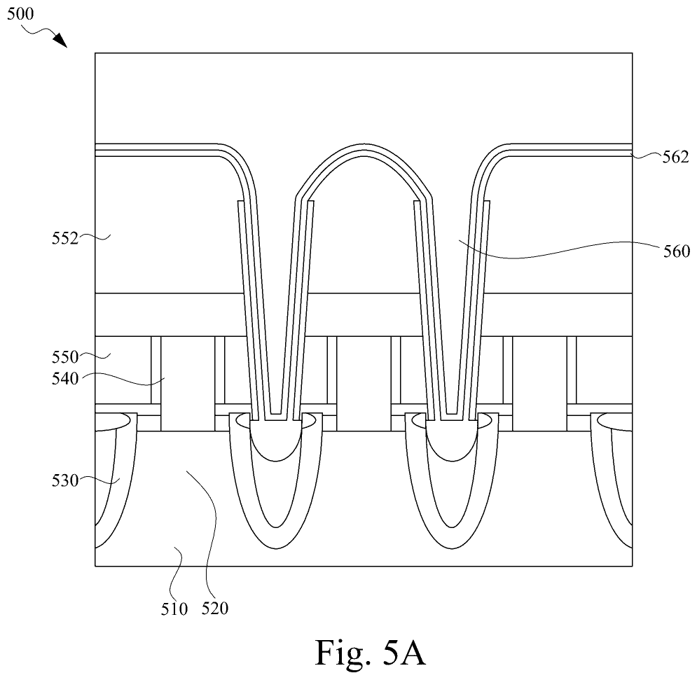

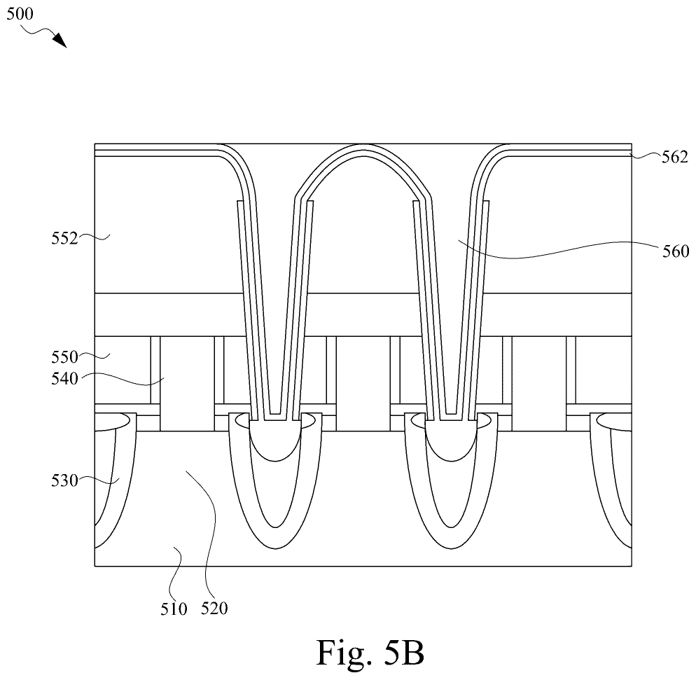

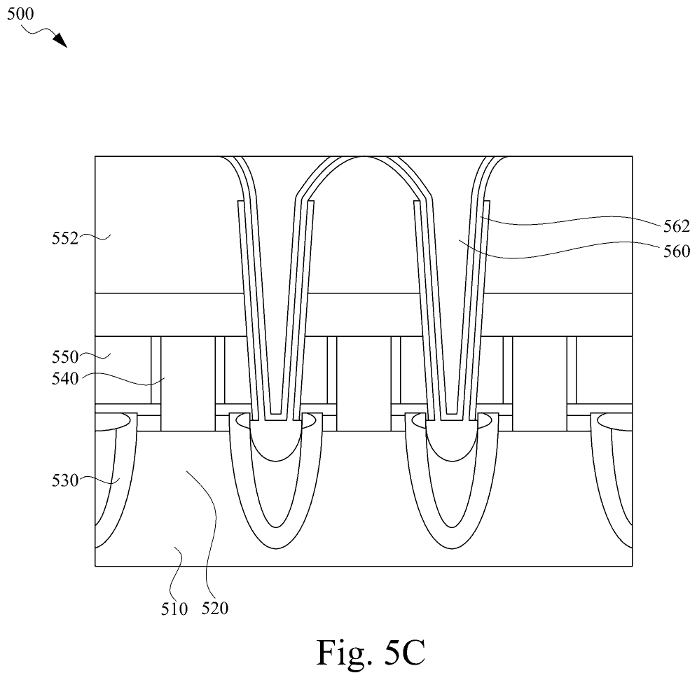

Embodiments of the present disclosure improves throughput and balanced transfer time to improve process uniformity. FIGS. 5A-5C schematically illustrate a semiconductor device 500 during fabrication at various stage of processing. A CMP process according to the present disclosure is performed when fabricating the semiconductor device 500. As shown, the semiconductor device 500 includes semiconductor fin 520 for FinFET transistors. The semiconductor device 500 are formed in or on a substrate 510. The substrate 510 may include a single crystalline semiconductor material such as, but not limited to Si, Ge, SiGe, GaAs, InSb, GaP, GaSb, InAlAs, InGaAs, GaSbP, GaAsSb, and InP. The semiconductor fin 520 is recessed etched and epitaxial source/drain regions 530 are formed from exposed semiconductor fin 520. Gate structures 540 are formed to a top surface and sidewalls of the semiconductor fin 520 between the source/drain regions 530. The gate structures 540 may include a gate dielectric layer, work-function metal layer, and a gate electrode layer.

An interlayer dielectric (ILD) layer 550 is formed over the source/drain regions 530 and between the gate structures 540. A second ILD layer 552 is disposed over the ILD layer 350 and the gate structures 540. The materials for the ILD layer 552 may be dielectric material including compounds comprising Si, O, C, and/or H, such as silicon oxide, SiCOH and SiOC. Organic materials, such as polymers, may be used for the ILD layer 552.

Contact openings may be formed through the ILD layer 550 and ILD layer 552 to expose the source/drain region 530. One or more liners layers 562 may be disposed in the contact openings and a conductive material 560 is deposed in the contact openings and over the ILD layer 552. The conductive material may be a metal, such as W, Ti, Ru, Mo, Co, Al, Cu, or compounds thereof. In some embodiments, the conductive material is filled in the contact holes by CVD, ALD, electro-plating, or other suitable method.

After the conductive material 560 is formed, a planarization operation, such as CMP, may be performed to remove the excessive conductive material 560 and expose the ILD layer 552, as shown in FIGS. 5B and 5C. In FIG. 5B, a bulk polishing process is performed to remove the majority of the excessive conductive material 560. In FIG. 5C, a fine polishing is performed remove the residual conductive material 560 and the liner layer 562 over the ILD layer 552 and expose the ILD layer 552 as shown in FIG. 5C.

Because the conductive material 560 may be susceptible to corrosion, using the CMP tool according to the present disclosure may reduce corrosion by reducing transfer time and polishing and cleaning the substrate in an inert environment.

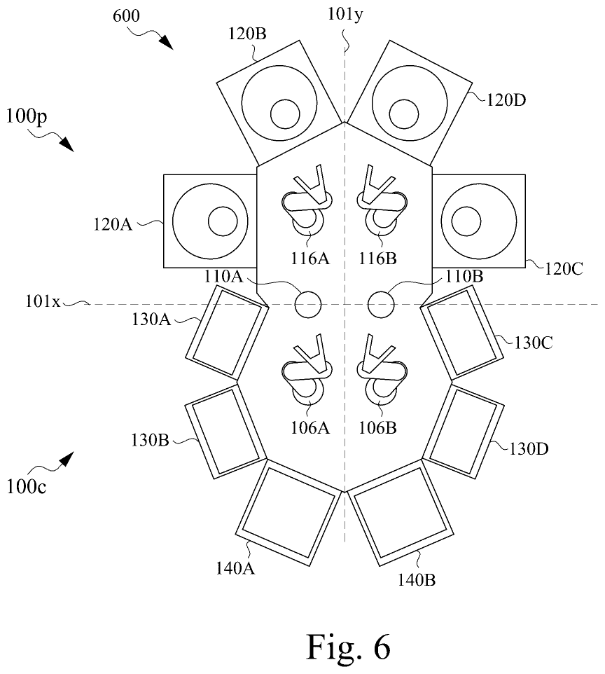

FIG. 6 is a schematic block diagram of a CMP tool 600 in accordance with some embodiments of the present disclosure. The CMP tool 600 is similar to the CMP tool 100 except that there are two substrate transfer robots in each transfer chambers 102, 112. As shown in FIG. 6A, the CMP tool 600 includes two substrate transfer robots 106A, 106B in the first transfer chamber 102 and two substrate transfer robots 116A, 116B in the second transfer chamber 112. In some embodiments, the substrate transfer robots 106A, 106B may be arranged symmetrically about the central axis 101y. The substrate transfer robots 116A, 116B may be arranged symmetrically about the central axis 101y.

The symmetrically arranged substrate transfer robots 116A/116B, 106A/106B may be used to symmetrically handle substrates during processing. For example, the substrate transfer robots 116A and 106A on the left side of the central axis 101y may be used to transfer substrates among the polishing chambers 120A and 120B and the cleaning chambers 130A, 130B on the left side of the central axis 101y while the substrate transfer robots 116B and 106B on the right side of the central axis 101y may be used to transfer substrates among the polishing chambers 120C and 120D and the cleaning chambers 130C, 130D on the right side of the central axis 101y.

The symmetric arrangement of the substrate transfer robots 116A/116B, 106A/106B enables the CMP tool 600 to simultaneously perform two different processes without cross contamination during substrate transfer. For example, the polishing chambers 120A, 120B and the cleaning chambers 130A, 130B and the substrate transfer robots 116A, 106A on the left side of the central axis 101y may be used to perform a first process, such as dielectric polishing while the polishing chambers 120C, 120D, the cleaning chambers 130C, 130D, and the substrate transfer robots 116B, 106B on the right side of the central axis 101y may be used to perform a second process, such as metal polishing.

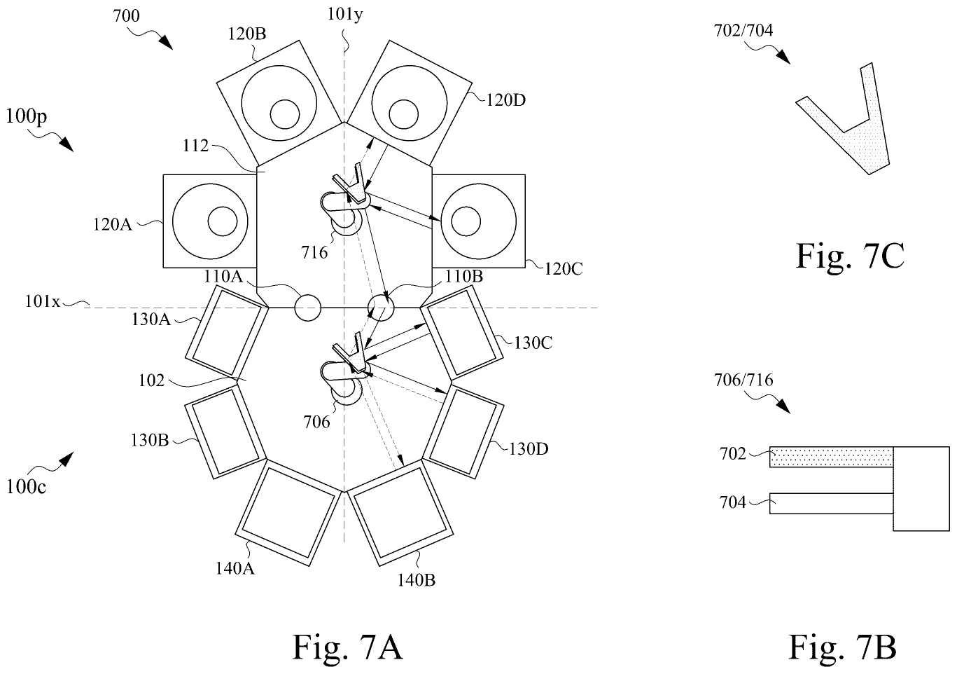

FIG. 7A is a schematic block diagram of a CMP tool 700 in accordance with some embodiments of the present disclosure. The CMP tool 700 is similar to the CMP tool 100 except that the CMP tool 700 includes substrate transfer robots 706, 716 having two or more blades. For example, the substrate transfer robots 706, 716 may include two more vertically stacked robot blades. Each blade may be designated to handle substrates during different processing steps to avoid cross contamination.

In some embodiments, as shown in FIG. 7B, the substrate transfer robot 706/716 may include an upper robot blade 702 vertically stacked over a lower robot blade 704. FIG. 7C is a schematic top view of the robot blades 702, 704. The upper and lower robot blades 702, 704 may have the identical structure and be dedicated to transfer substrates at different stages of the processing. For example, the upper robot blade 702 may be used to transfer dry substrates while the lower robot blade 704 may be used to transfer wet substrate, therefore, preventing contamination between dry and wet substrates.

FIG. 7A includes schematically illustrates a substrate path on the upper and lower robot blades while being processed by the polishing chambers 120D, 120C and cleaning chambers 130C, 130D. Table 2 below includes the details of a substrate path via a dry robot blade, such as the upper robot blade 702, and a wet robot blade, such as the bottom robot blade 704.

TABLE 2

| Description of Process Sequence | Substrate Path |
|---|---|
| Transfer 1 on the upper blade 702 | 140B to 110B |
| From FOUP to wafer station | Travel Distance: 2*D₁₃₀ |
| Transfer 2 on the upper blade 702 | 110B to 120D |
| From Wafer station to first polishing | Travel Distance: 2*D₁₂₀ |
| station | |
| Rough Polish | 120D |
| Transfer 3 on the lower blade 704 | 120D to 120C |
| From first polishing station to second | Travel Distance: 2*D₁₂₀ |
| polishing station | |
| Fine Polish | 120C |
| Transfer 4 on the lower blade 704 | 120C to 110B |
| From second polishing station to wafer | Travel Distance: 2*D₁₂₀ |
| station | |
| Transfer 5 on the lower blade 704 | 110B to 130C |
| From wafer station to the first cleaning | Travel Distance: 2*D₁₃₀ |
| station | |
| First cleaning | 130C |
| Transfer 6 on the lower blade 704 | 130C to 130D |
| From first cleaning station to second | Travel Distance: 2*D₁₃₀ |
| cleaning station | |
| Second cleaning | 130D |
| Transfer 7 on the upper blade 702 | 130D to 140B |
| From second cleaning station to FOUP | Travel Distance: 2*D₁₃₀ |

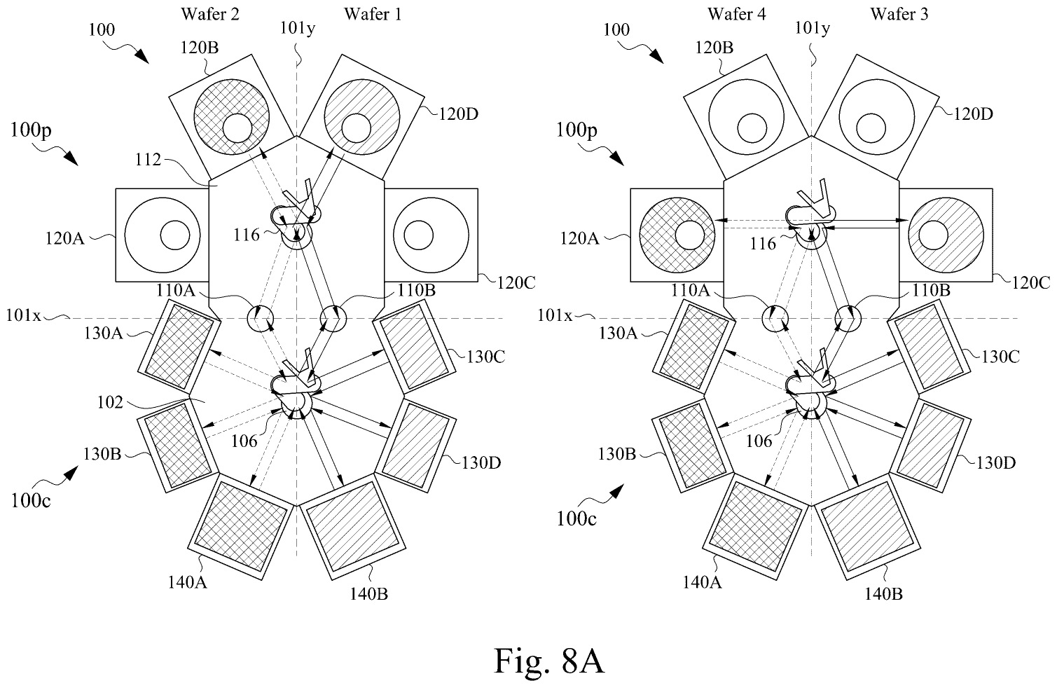

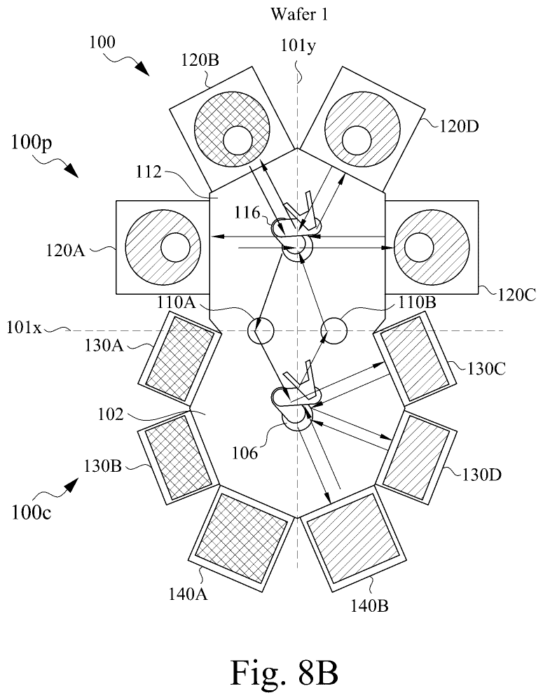

FIGS. 8A-8B schematically demonstrate various processing sequences using CMP tools according to embodiments of the present disclosure.

FIG. 8A schematically demonstrates a process sequence with one platen polishing using the CMP tool 100. As shown in Table 3, the CMP tool 100 may run four parallel wafer paths simultaneously.

TABLE 3

| Description of | | | | |
|---|---|---|---|---|
| Process Sequence | Wafer 1 Path | Wafer 2 Path | Wafer 3 Path | Wafer 4 Path |
| Transfer 1 | 140A to 110A | 140B to 110B | 140A to 110A | 140B to 110B |
| From FOUP to wafer | | | | |
| station | | | | |
| Transfer 2 | 110A to 120B | 110B to 120D | 110A to 120A | 110B to 120C |
| From Wafer station | | | | |
| to first polishing | | | | |
| station | | | | |
| Polish | 120B | 120D | 120A | 120C |
| Transfer 3 | 120B to 110A | 120D to 110B | 120A to 110A | 120C to 110B |
| From second | | | | |
| polishing station to | | | | |
| wafer station | | | | |
| Transfer 4 | 110A to 130A | 110B to 130C | 110A to 130A | 110B to 130C |
| From wafer station to | | | | |
| the first cleaning | | | | |
| station | | | | |
| First cleaning | 130A | 130C | 130A | 130C |
| Transfer 5 | 130A to 130B | 130C to 130D | 130A to 130B | 130C to 130D |
| From first cleaning | | | | |
| station to second | | | | |
| cleaning station | | | | |
| Second cleaning | 130B | 130D | 130B | 130D |
| Transfer 6 | 130B to 140A | 130D to 140B | 130B to 140A | 130D to 140B |
| From second | | | | |
| cleaning station to | | | | |
| FOUP | | | | |

FIG. 8B schematically demonstrates a process sequence with four platen polishing using the CMP tool 100. Two wafer paths may be implemented using the CMP tool 100. As shown in Table 4, wafer 1 path and wafer 2 path share the same path through the polishing module 100p but differ through the cleaning module 100c.

TABLE 4

| Description of Process Sequence | Wafer 1 Path | Wafer 2 Path (not shown) |
|---|---|---|
| Transfer 1 | 140B to 110B | 140A to 110B |
| From FOUP to wafer station | Travel Distance: 2*D₁₃₀ | Travel Distance: 2*D₁₃₀ |
| Transfer 2 | 110B to 120D | 110B to 120D |
| From Wafer station to first polishing | Travel Distance: 2*D₁₂₀ | Travel Distance: 2*D₁₂₀ |
| station | | |
| First Polish | 120D | 120D |
| Transfer 3 | 120D to 120C | 120D to 120C |
| From first polishing station to second | Travel Distance: 2*D₁₂₀ | Travel Distance: 2*D₁₂₀ |
| polishing station | | |
| Second Polish | 120C | 120C |
| Transfer 4 | 120C to 120B | 120C to 120B |
| From second polishing station to third | Travel Distance: 2*D₁₂₀ | Travel Distance: 2*D₁₂₀ |
| polishing station | | |
| Third Polish | 120B | 120B |
| Transfer 5 | 120B to 120A | 120B to 120A |
| From third polishing station to fourth | Travel Distance: 2*D₁₂₀ | Travel Distance: 2*D₁₂₀ |
| polishing station | | |
| Fourth Polish | 120A | 120A |
| Transfer 6 | 120A to 110A | 120A to 110A |
| From fourth polishing station to wafer | Travel Distance: 2*D₁₂₀ | Travel Distance: 2*D₁₂₀ |
| station | | |
| Transfer 7 | 110A to 130C | 110A to 130A |
| From wafer station to the first cleaning | Travel Distance: 2*D₁₃₀ | Travel Distance: 2*D₁₃₀ |
| station | | |
| First cleaning | 130C | 130A |
| Transfer 8 | 130C to 130D | 130A to 130B |
| From first cleaning station to second | Travel Distance: 2*D₁₃₀ | Travel Distance: 2*D₁₃₀ |
| cleaning station | | |
| Second cleaning | 130D | 130B |
| Transfer 9 | 130D to 140B | 130B to 140B |
| From second cleaning station to FOUP | Travel Distance: 2*D₁₃₀ | Travel Distance: 2*D₁₃₀ |

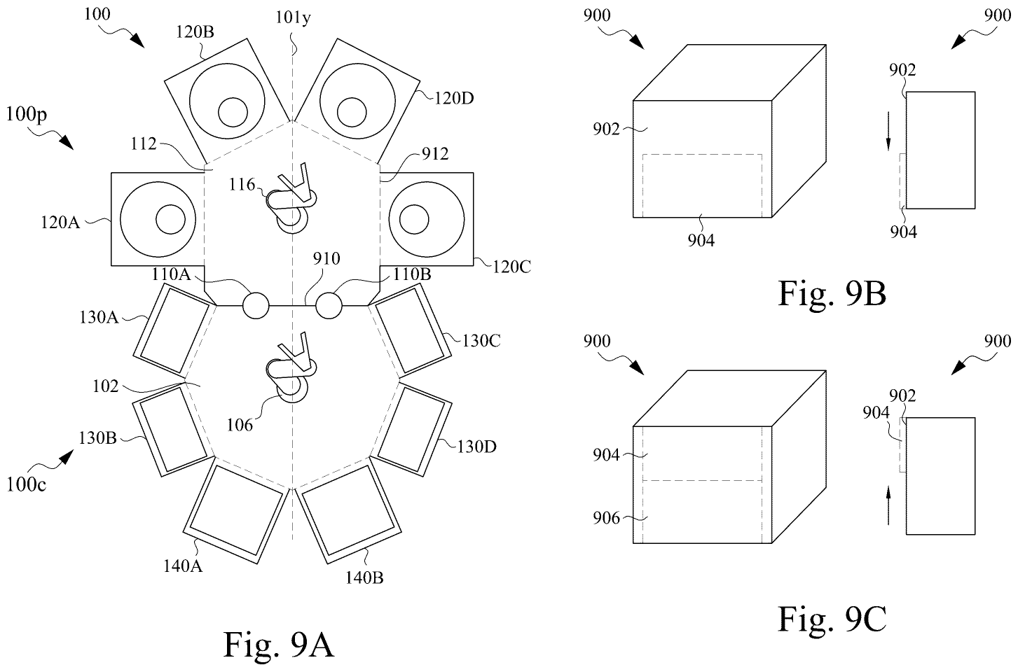

FIGS. 9A-9C schematically demonstrate a cleaner/polisher with a movable door according to embodiments of the present disclosure. FIG. 9A is a schematic plan view of the CMP tool 100. In FIG. 9A, solid walls are shown in solid lines, such as walls 910 between the transfer chambers 112, 102, and movable walls are shown in dashed lines, such as walls 912 between the transfer chambers 102/112 and the cleaning chamber 130/polishing chamber 120. In some embodiments, the polishing chambers 120/cleaning chambers 130 may have a movable door.

FIGS. 9B and 9C schematically demonstrate a chamber 900 with a movable door 904 according to embodiments of the present disclosure. The chamber 900 may be a polishing chamber or a cleaning chamber. The chamber 900 may be used as the polishing chambers 120 and the polishing chambers 130 in the CMP tools of the present disclosure.

FIG. 9B includes a perspective view and a side view of the chamber 900 with the movable door 904 in a closed position. FIG. 9C includes a perspective view and a side view of the chamber 900 with the movable door 904 in an open position. As shown in FIGS. 9B and 9C, the chamber 900 includes a wall 902 configured to connect with the transfer chamber. An opening 906 is formed through the wall 902. The movable door 904 may be selectively open and close to selectively open and close an inner volume of the chamber 900. In FIGS. 9B and 9C, the movable door 904 may be raised or lowered to open and close. Alternatively, the movable door 904 may be open or close by other mechanism, such as by hinges. The movable door 900 may be closed during wafer processing, periodic maintenance, trouble shooting, or idle period. The movable door 900 may be close during wafer transfer mode to allow passage of wafers there through. The movable door 904 provides interface transfer chamber and the polishing/cleaning chamber during processing, therefore, reducing contamination.

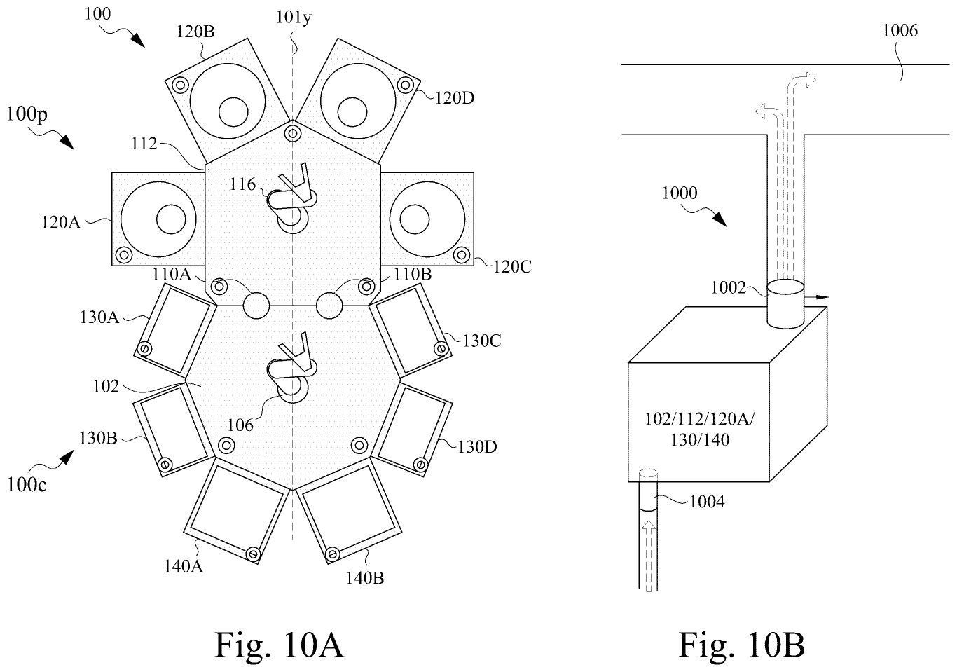

FIGS. 10A-10B schematically demonstrate a cleaner/polisher with inert gas fill function according to embodiments of the present disclosure. FIG. 10A is a schematic plan view of the CMP tool 100 having exhaust tubes 1002. The exhaust tubes 1002 may be equipped on one or more polishing chambers 120, one or more cleaning chambers 130, and/or one or more transfer chambers 102, 112.

FIG. 10B is a schematic view of a chamber 1000 capable of maintaining an inert environment according to embodiments of the present disclosure. The chamber 1000 may be a polishing chamber, such as the polishing chamber 120, a cleaning chamber, such as the cleaning chamber 130, or a transfer chamber, such as the transfer chamber 102, 112. The chamber 1000 may include an inlet 1004 configured to connect with a gas supply. The inlet 1004 may be connected to a gas supply so that an inert gas, such as nitrogen, may be supplied to the chamber 1000. The chamber 1000 further includes an exhaust tube 1002. The exhaust tube 1002 may be connected to an exhaust system 1006, such a vacuum exhaust. The exhaust tube 1002 allows inert gas from the inlet 1004 to fill the inner volume of the chamber 1000, then flow out the exhaust tube 1002 to the system exhaust. The filled inert gas in the chamber 1000 prevents corrosion on polished substrate surface.

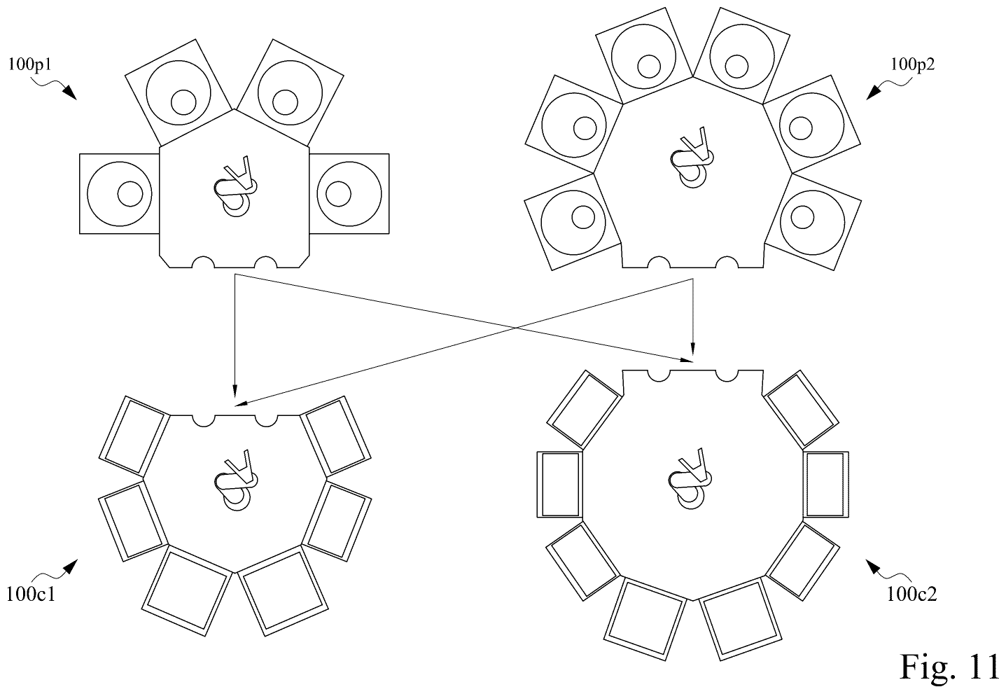

FIG. 11 schematically demonstrate modular CMP tools according to embodiments of the present disclosure. In some embodiments, the CMP tools according to the present disclosure may be modular tools assembled together by combining a polishing module and a cleaning module. In FIG. 11, two polishing modules 100p1, 100p2 and two cleaning modules 100c1, 100c2. The polishing modules 100p1 and 100p2 have different numbers of polishing stations. Each polishing module 100p1 and 100p1 has the same interface configured to connect with multiple cleaning modules. The cleaning modules 100c1, 100c2 may have different numbers of cleaning stations. Each cleaning module 100c1 and 100c1 has the same interface configured to connect with multiple polishing modules. The polishing modules 100p1, 100p2 and the cleaning modules 100c1, 100c2 can be assembled according to the processing needs.

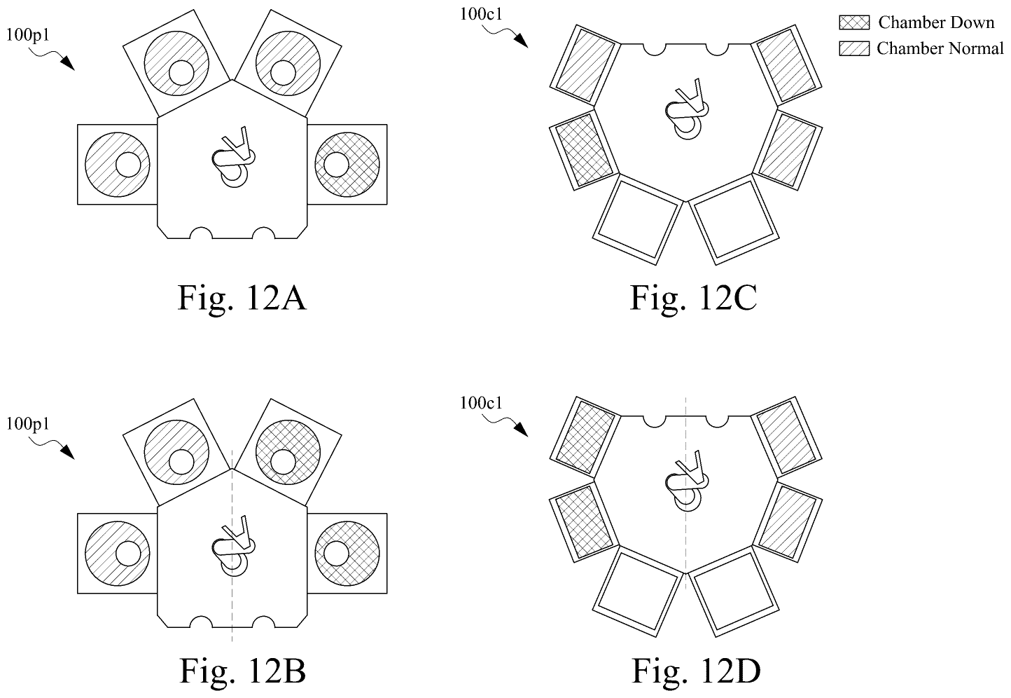

Polishing chambers in the polishing modules and cleaning chambers of the cleaning modules of the present disclosure may be shut down individually or in group for trouble shooting or periodical maintenance without shutting down the system. FIGS. 12A-12D schematically demonstrate trouble shooting or maintenance mode of polishing/cleaning modules according to embodiments of the present disclosure.

FIG. 12A schematically demonstrate a trouble shooting mode of the polishing module 100p1. In FIG. 12A, one polishing chamber is shut down for trouble shooting while other polishing chambers maintain normal operation.

FIG. 12B schematically demonstrate a periodical maintenance mode of the polishing module 100p1. In FIG. 12B, polishing chambers on one side of the central axis are shut down for maintenance while polishing chambers on the other side of the central axis maintain normal operation.

FIG. 12C schematically demonstrate a trouble shooting mode of the cleaning module 100c1. In FIG. 12C, one cleaning chamber is shut down for trouble shooting while other cleaning chambers maintain normal operation.

FIG. 12D schematically demonstrate a periodical maintenance mode of the cleaning module 100c1. In FIG. 12D, cleaning chambers on one side of the central axis are shut down for maintenance while cleaning chambers on the other side of the central axis maintain normal operation.

Various embodiments or examples described herein offer multiple advantages over the state-of-art technology. Embodiments of the present disclosure reduce corrosion and improve throughput.

It will be understood that not all advantages have been necessarily discussed herein, no particular advantage is required for all embodiments or examples, and other embodiments or examples may offer different advantages.

Some embodiments of the present provide a semiconductor processing tool, comprising: a first transfer chamber; a plurality of polishing chambers attached to the first transfer chamber, wherein each polishing chamber comprises: a chamber body defining a chamber volume; a polishing station disposed in the chamber volume; and a door selectively isolating the chamber volume from the first transfer chamber; and a first substrate transfer robot disposed in the first transfer chamber and configured to transfer substrates among the plurality of polishing chambers.

Some embodiments of the present disclosure provide a semiconductor processing tool, comprising: a first transfer chamber; a second transfer chamber; first and second wafer stations disposed between the first and second transfer chambers; a plurality of polishing chambers connected to the first transfer chamber; a first substrate transfer robot disposed in the first transfer chamber and configured to transfer substrates among the plurality of polishing chambers and the first and second wafer stations; a plurality of cleaning chambers connected to the second transfer chamber; and a second substrate transfer robot disposed in the second transfer chamber and configured to transfer substrates among the plurality of cleaning chambers and the first and second wafer stations.

Some embodiments of the present disclosure provide a method comprising picking up a substrate using a substrate transfer robot disposed in a transfer chamber; dropping off the substrate to a first polishing chamber attached to the transfer chamber, wherein the first polishing chamber comprises a chamber body defining a chamber volume; polishing the substrate in the first polishing chamber while supplying an inert gas to the chamber volume; and retrieving the substrate from the first polishing chamber using the substrate transfer robot.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor processing tool, comprising:
a first transfer chamber;
a plurality of polishing chambers attached to the first transfer chamber, wherein each polishing chamber comprises:
a chamber body defining a chamber volume;
a polishing station disposed in the chamber volume; and
a door selectively isolating the chamber volume from the first transfer chamber; and
a first substrate transfer robot disposed in the first transfer chamber and configured to transfer substrates among the plurality of polishing chambers.

2. The semiconductor processing tool of claim 1, wherein the plurality of polishing chambers are symmetrically arranged about the first transfer chamber.

3. The semiconductor processing tool of claim 2, further comprising:
a second transfer chamber;
two or more cleaning chambers attached to the second transfer chamber; and
a second substrate transfer robot disposed in the second transfer chamber and configured to the transfer substrates among the two or more cleaning chambers.

4. The semiconductor processing tool of claim 3, further comprising:
a load cup disposed between the first and second transfer chambers.

5. The semiconductor processing tool of claim 3, further comprising:
a wafer station disposed between the first and second transfer chambers, wherein the first and second transfer chambers are selectively isolated from each other.

6. The semiconductor processing tool of claim 3, wherein each of the two or more cleaning chambers comprises:
a cleaning chamber body defining a cleaning volume;
a cleaning station disposed in the cleaning volume; and
a door disposed between the cleaning volume and the second transfer chamber.

7. The semiconductor processing tool of claim 3, further comprises an interface chamber attached to the second transfer chamber, wherein the interface chamber is configured to receive a front opening unified pod (FOUP).

8. A semiconductor processing tool, comprising:
a first transfer chamber;
a second transfer chamber;
first and second wafer stations disposed between the first and second transfer chambers;
a plurality of polishing chambers connected to the first transfer chamber;
a first substrate transfer robot disposed in the first transfer chamber and configured to transfer substrates among the plurality of polishing chambers and the first and second wafer stations;
a plurality of cleaning chambers connected to the second transfer chamber; and
a second substrate transfer robot disposed in the second transfer chamber and configured to transfer substrates among the plurality of cleaning chambers and the first and second wafer stations.

9. The semiconductor processing tool of claim 8, further comprising:
first and second interface chambers attached to the second transfer chamber, wherein each of the first and second interface chambers is configured to receive a front opening unified pod (FOUP).

10. The semiconductor processing tool of claim 8, wherein the plurality of polishing chambers are symmetrically arranged about the first transfer chamber.

11. The semiconductor processing tool of claim 10, wherein each of the plurality of transfer chambers comprises:
a chamber body defining a chamber volume;
a polishing station disposed in the chamber volume; and
a door selectively isolating the chamber volume from the first transfer chamber.

12. The semiconductor processing tool of claim 11, wherein each of the plurality of transfer chambers further comprises:
a conduit adapted to connect with a gas supply; and
an exhaust connected to the chamber volume.

13. A method, comprising:
picking up a substrate using a substrate transfer robot disposed in a transfer chamber;
dropping off the substrate to a first polishing chamber attached to the transfer chamber, wherein the first polishing chamber comprises a chamber body defining a chamber volume;
polishing the substrate in the first polishing chamber while supplying an inert gas to the chamber volume; and
retrieving the substrate from the first polishing chamber using the substrate transfer robot.

14. The method of claim 13, wherein dropping off the substrate to the first polishing chamber comprises:
opening a door between the first polishing chamber and the transfer chamber to allow the substrate transfer robot into the chamber volume.

15. The method of claim 13, further comprising:
after retrieving the substrate from the first polishing chamber, dropping off the substrate to a second polishing chamber attached to the transfer chamber;
polishing the substrate in the second polishing chamber; and
retrieving the substrate from the second polishing chamber using the substrate transfer robot.

16. The method of claim 13, further comprising:
transferring the substrate from a FOUP to a load cup, wherein picking up the substrate comprises picking up the substrate from the load cup.

17. The method of claim 16, further comprising:
returning the substrate to the load cup; and
picking up the substrate using a second substrate transfer robot disposed in a second transfer chamber;
dropping off the substrate at a first cleaning chamber connected to the second transfer chamber; and
cleaning the substrate in the first cleaning chamber.

18. The method of claim 17, wherein cleaning the substrate in the first cleaning chamber comprises: supplying an inert gas to the first cleaning chamber.

19. The method of claim 17, further comprising:
picking up the substrate from the first cleaning chamber using the second substrate transfer robot;
dropping off the substrate at a second cleaning chamber connected to the second transfer chamber; and
cleaning the substrate in the second cleaning chamber.

20. The method of claim 17, further comprising:
returning the substrate to the FOUP using the second substrate transfer robot.
